(19) United States
(12) Patent Application Publication
(10) Pub. No.: US 2026/0155464 A1
(43) Pub. Date: Jun. 4, 2026

(54) INRUSH CURRENT-BASED CONTACTOR CLOSURE

(71) Applicant: LG ENERGY SOLUTION, LTD., Seoul (KR)

(72) Inventors: Sagar Nagaluru, Rochester Hills, MI (US); Mohammad Rupok, Sterling Heights, MI (US); Sandeep Vankineni, Northville, MI (US); Bhavya Jampani, Warren, MI (US)

(73) Assignee: LG ENERGY SOLUTION, LTD., Seoul (KR)

(21) Appl. No.: 18/968,685

(22) Filed: Dec. 4, 2024

(51) Int. Cl. H01M 10/42; H01M 50/204; H01M 50/258; H01M 50/296

(52) U.S. Cl. CPC H01M 10/425; H01M 50/204; H01M 50/258; H01M 50/296; H01M 2010/4271

(57) ABSTRACT

A battery system for balancing battery subpacks may be provided. The battery system may include a plurality of battery subpacks and a master microprocessor. Each of the battery subpacks may include a battery module, a primary positive contactor, an auxiliary positive contactor, a negative contactor, and a subpack microprocessor configured to open and close the primary positive contactor, the auxiliary positive contactor, and the negative contactor. The master microprocessor may be in electrical communication with the subpack microprocessor of each of the battery subpacks. The master microprocessor may be configured to receive information about a voltage value of the battery module of each of the battery subpacks, and sort the plurality of battery subpacks according to the voltage value of the battery subpacks.

### TECHNICAL FIELD

Various embodiments of the present disclosure relate generally to methods and systems for balancing battery subpacks, and more particularly, to battery management methods and battery management systems for controlling contactors of battery subpacks to balance the battery subpacks effectively, for example, without using complex balancing circuit.

### BACKGROUND

Batteries are increasingly being integrated into a wide range of mobile devices, including smartphones, laptops, electric vehicles (EVs), hybrid electric vehicles (HEVs), plug-in hybrid electric vehicles (PHEVs), and energy storage systems (ESS). To ensure optimal performance and safety, these batteries are often paired with a Battery Management System (BMS) that oversees their overall operation. In particular, larger battery packs used in vehicles or energy storage systems typically consist of multiple battery modules. These modules are arranged in a multi-module configuration, allowing them to be connected in series and/or parallel.

Parallel battery packs in a Battery Management System (BMS) may frequently encounter pack imbalance issues, resulting in suboptimal performance and shortened lifespan. This imbalance may occur due to variations in cell characteristics, manufacturing tolerances, and uneven aging of individual cells within the pack. As batteries charge and discharge over time, these differences can become more pronounced, leading to some cells or packs carrying a disproportionate share of the load. This uneven distribution of charge and discharge cycles can accelerate degradation in certain cells, further exacerbating the imbalance and potentially compromising the overall system reliability.

Conventional methods for addressing pack imbalance typically involve passive or active balancing techniques, which can be complex and costly to implement. For example, passive balancing may rely on draining excess energy from higher-charged cells through resistors and dissipating it as heat, while active balancing may redistribute charge between cells using more sophisticated circuitry. While these approaches can be effective, they often require additional components and careful design considerations, potentially increasing system complexity and cost.

### SUMMARY OF THE DISCLOSURE

According to certain aspects of the disclosure, methods and systems are disclosed for controlling contactors of battery subpacks to balance the battery subpacks effectively, for example, without using complex balancing circuit.

For instance, a battery system for balancing battery subpacks may include a plurality of battery subpacks, each of the battery subpacks comprising: a battery module; a primary positive contactor; an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module; a negative contactor being electrically connected to the negative terminal of the battery module; and a subpack microprocessor configured to open and close the primary positive contactor, the auxiliary positive contactor, and the negative contactor; and a master microprocessor in electrical communication with the subpack microprocessor of each of the battery subpacks, wherein the master microprocessor is configured to receive information about a voltage value of the battery module of each of the battery subpacks, wherein the plurality of battery subpacks comprise a first battery subpack and a second battery subpack, wherein the master microprocessor is further configured to: sort the plurality of battery subpacks according to the voltage value of the battery subpacks; determine whether a difference between a voltage value of the first battery subpack and a voltage value of the second battery subpack is equal to or less than a first predetermined threshold value; and responsive to determining that the difference between the voltage value of the first battery subpack and the voltage value of the second battery subpack is equal to or less than the first predetermined threshold value, connect the first battery subpack with the second battery subpack by closing contactors of the first and second battery subpacks.

A method of operating a battery system, wherein the battery system comprises: a plurality of battery subpacks, each of the battery subpacks comprising: a battery module; a primary positive contactor; an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module; a negative contactor being electrically connected to the negative terminal of the battery module; and a subpack microprocessor configured to open and close the primary positive contactor, the auxiliary positive contactor, and the negative contactor; and a master microprocessor in electrical communication with the subpack microprocessor of each of the battery subpacks, wherein the master microprocessor is configured to receive information about a voltage value of the battery module of each of the battery subpacks, wherein the plurality of battery subpacks comprise a first battery subpack and a second battery subpack, wherein the method may include: sorting, by the master microprocessor, the plurality of battery subpacks according to the voltage value of the battery subpacks; determining, by the master microprocessor, whether a difference between a voltage value of the first battery subpack and a voltage value of the second battery subpack is equal to or less than a first predetermined threshold value; and responsive to determining that the difference between the voltage value of the first battery subpack and the voltage value of the second battery subpack is equal to or less than the first predetermined threshold value, connecting the first battery subpack with the second battery subpack by closing contactors of the first and second battery subpacks.

A battery system for balancing battery subpacks may include a plurality of battery subpacks, each of the battery subpacks comprising: a battery module; a primary positive contactor; an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module; a negative contactor being electrically connected to the negative terminal of the battery module; and a subpack microprocessor configured to open and close the primary positive contactor, the auxiliary positive contactor, and the negative contactor; and a master microprocessor in electrical communication with the subpack microprocessor of each of the battery subpacks, wherein the master microprocessor is configured to receive information about a voltage value of the battery module of each of the battery subpacks, wherein the plurality of battery subpacks comprise a first battery subpack, a second battery subpack, a third battery subpack, and a fourth battery subpack, wherein the master microprocessor is further configured to: sort the first, second, third, and fourth battery subpacks according to the voltage value of the first, second, third, and fourth battery subpacks, wherein a voltage value of the fourth battery subpack is equal to or greater than a voltage value of the third battery subpack, wherein a voltage value of the third battery subpack is equal to or greater than a voltage value of the second battery subpack, and wherein a voltage value of the second battery subpack is equal to or greater than a voltage value of the first battery subpack, determine whether a difference between the voltage value of the first battery subpack and the voltage value of the second battery subpack is equal to or less than a first predetermined threshold value; determine whether a difference between the voltage value of the third battery subpack and the voltage value of the fourth battery subpack is equal to or less than the first predetermined threshold value; and determine whether a difference between an average of the voltage values of the first and second battery subpacks and an average of the voltage values of the third and fourth battery subpacks is equal to or greater than a second predetermined threshold value.

Additional objects and advantages of the disclosed embodiments will be set forth in part in the description that follows, and in part will be apparent from the description, or may be learned by practice of the disclosed embodiments.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which are incorporated in and constitute a part of this specification, illustrate various exemplary embodiments and together with the description, serve to explain the principles of the disclosed embodiments.

FIG. 1 illustrates an exemplary block diagram of a system for balancing battery subpacks according to an example of the present disclosure.

FIG. 2 illustrates an exemplary block diagram of a system for balancing battery subpacks according to an example of the present disclosure.

FIGS. 3A-3F illustrate a flow diagram of example methods 300A-300F for operating a plurality of battery subpacks according to an example embodiment of the present disclosure.

FIG. 4 illustrates an example of a table having a predetermined contactor control configuration according to an example embodiment of the present disclosure.

### DETAILED DESCRIPTION OF EMBODIMENTS

In general, the present disclosure is directed to battery management methods and battery management systems for controlling contactors of battery subpacks to balance the battery subpacks effectively, for example, without using complex balancing circuit.

Aspects of the present disclosure may mitigate pack imbalance in parallel battery packs by utilizing the inrush current rating of contactors. By intelligently closing contactors based on a certain range of inrush currents, the system according to aspects of the present disclosure can balance the battery subpacks effectively without the need for complex balancing circuits.

In some aspects, the system according to an example of the present disclosure may involve a BMS that may monitor the inrush current of each parallel pack’s contactors, for example, during the initial connection phase. Based on predetermined thresholds and the battery subpacks’ individual state of charge, the BMS may selectively close contactors to balance the battery subpacks. Aspects of the present disclosure can be implemented in existing BMSs without or with minimal hardware modifications, for example, by updating the BMS/system logic/algorithm/software to include the inrush current monitoring and contactor control logic.

In this way, aspects of the present disclosure may eliminate the need for complex passive or active balancing circuits, thereby reducing overall system complexity. Moreover, by utilizing existing contactors and monitoring circuits, aspects of the present disclosure may minimize additional hardware costs. In addition, the system according to an example of the present disclosure may intelligently balance battery subpacks based on inrush current, thereby ensuring optimal performance and longevity of parallel battery packs.

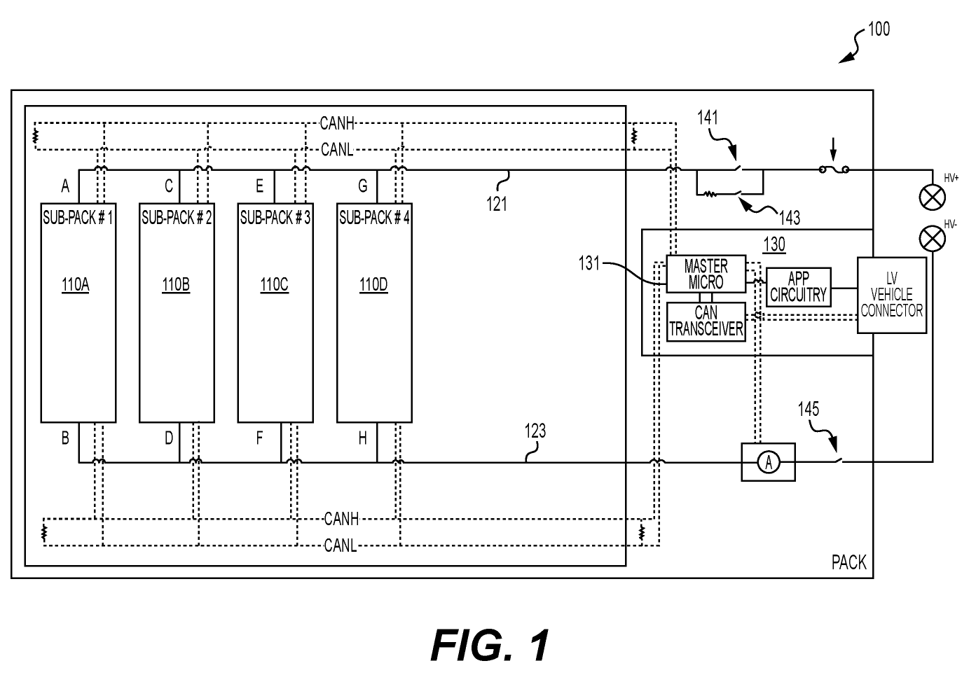

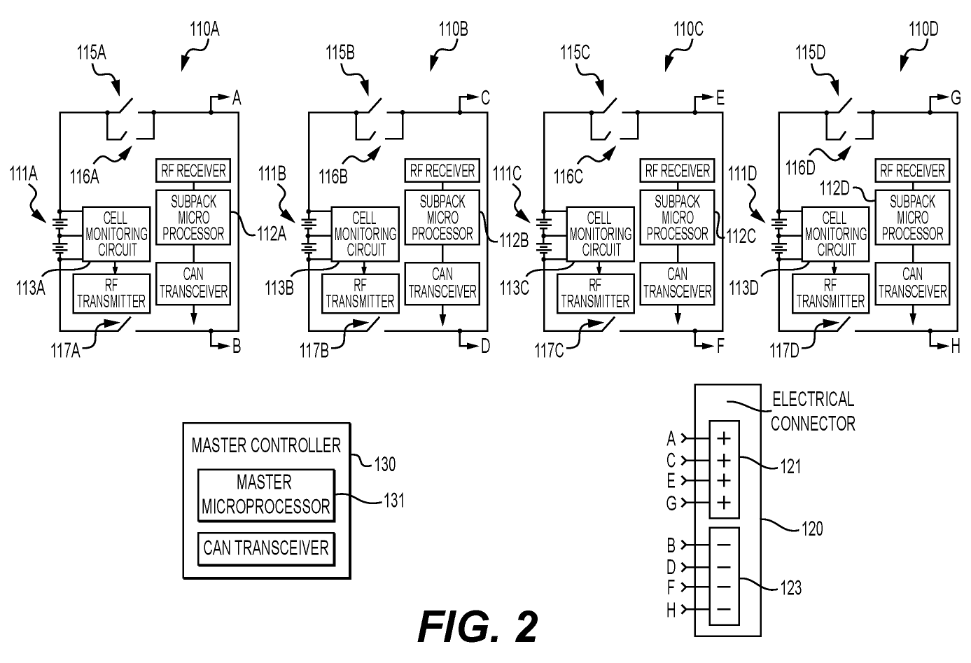

FIGS. 1 and 2 depict an exemplary block diagram of a system 100 for balancing battery subpacks. In some examples, the system 100 may be a Battery Management System (BMS) configured to monitor, manage, and/or protect battery packs. In some examples, the system 100 may be part of a mobile device, such as an electric vehicle, a hybrid electric vehicle, a plug-in hybrid electric vehicle, a smartphones, a laptop, and an energy storage system.

As shown in FIGS. 1 and 2, the system 100 may include a plurality of battery subpacks 110A-110D, an electrical connector 120, and a master controller 130. Although there are four battery subpacks shown in FIG. 2, the number of battery subpacks can be more or less than four (e.g., 2, 3, 5, 6, 7, 8, 9, 10, …). As shown in FIG. 2, in some examples, each of the battery subpacks 110A-110D may include a battery module 111A-111D, a subpack microprocessor 112A-112D, a cell monitoring circuit 113A-113D, a primary positive contactor 115A-115D, an auxiliary positive contactor 116A-116D, and/or a negative contactor 117A-117D.

In some examples, each battery module 111A-111D of the battery subpacks 110A-110D may include a plurality of battery submodules. In some examples, the number of the battery submodules in each of the battery modules 111A-111D may be in a range of about 8 to 64 submodules. For example, each of the battery modules 111A-111D may include 8, 16, 32, or 64 submodules. In other examples, each of the battery modules 111A-111D may include any other suitable number of battery submodules.

In some examples, each of the battery submodules may include multiple battery cells. In some examples, the number of the battery cells in each of the battery submodules may be in a range of 2 to 64 battery cells. For example, each of the battery submodules may include 2, 4, 8, 16, 32, or 64 battery cells. In other examples, each of the battery submodules may include any other suitable number of battery cells.

The primary positive contactor 115A-115D and the auxiliary positive contactor 116A-116D may be electrically connected to a positive terminal of the battery module 111A-111D, and the negative contactor 117A-117D may be electrically connected to the negative terminal of the battery module 111A-111D. In some examples, the primary positive contactor 115A-115D and the auxiliary positive contactor 116A-116D may be electrically connected in parallel to one another. The auxiliary positive contactor 116A-116D may be a pack balancing contactor that is used to withstand an inrush current.

In some examples, the cell monitoring circuit 113A-113D may be configured to detect the voltage and/or current value of the battery module 111A-111D. In some examples, the cell monitoring circuit 113A-113D may be configured to transmit information about the voltage and/or current value of the battery module 111A-111D to the respective subpack microprocessor 112A-112D within the same battery subpack 110A-110D, for example, through a transmitter (e.g., RF transmitter).

The subpack microprocessor 112A-112D may be configured to receive the information about the voltage and/or current value of the battery module 111A-111D from the cell monitoring circuit 113A-113D, for example, through a receiver (e.g., RF receiver). The subpack microprocessor 112A-112D may be further configured to open and close the primary positive contactor 115A-115D, the auxiliary positive contactor 116A-116D, and the negative contactor 117A-117D. In some examples, the subpack microprocessor 112A-112D may transmit/receive data to/from the cell monitoring circuit 113A-113D wirelessly as shown in FIG. 2. In other examples, the subpack microprocessor 112A-112D may transmit/receive data to/from the cell monitoring circuit 113A-113D via a wired connection.

In some examples, the master controller 130 may include a master microprocessor 131. The subpack microprocessor 112A-112D may be configured to transmit the information about the voltage and/or current value of the battery module 111A-111D to the master microprocessor 131, for example, through a transmitter (e.g., CAN transmitter). The master microprocessor 131 may be configured to receive the information about the voltage and/or current value of the battery module 111A-111D from the subpack microprocessor 112A-112D, for example, through a receiver (e.g., CAN receiver). In some examples, the master microprocessor 131 may transmit/receive data to/from the subpack microprocessor 112A-112D wirelessly as shown in FIG. 2. In other examples, the master microprocessor 131 may transmit/receive data to/from the subpack microprocessor 112A-112D via a wired connection.

The master microprocessor 131 may be configured to control all or some components of the battery subpacks 110A-110D, for example, by using the respective subpack microprocessor 112A-112D. For example, the master microprocessor 131 may be configured to open and close the primary positive contactor 115A-115D, the auxiliary positive contactor 116A-116D, and the negative contactor 117A-117D, for example, by transmitting opening/closing commands to the respective subpack microprocessor 112A-112D.

In some examples, the electrical connector 120 may include a positive electrical connector 121 and a negative electrical connector 123. The battery subpacks 110A-110D may be connected to each other in parallel through the positive electrical connector 121 and the negative electrical connector 123. For example, the positive electrical connector 121 may be connected to the positive/auxiliary positive contactors of the battery subpacks 110A, 110B, 110C, 110D through nodes A, C, E, G, respectively. Similarly, the negative electrical connector 123 may be connected to the negative contactors of the battery subpacks 110A, 110B, 110C, 110D through nodes B, D, F, H, respectively.

In some examples, the positive electrical connector 121, the negative electrical connector 123, and/or the nodes A-H may be made with a conductive material, such as a metal (e.g., copper) or any other suitable conductive material.

In some examples, the system 100 may further include a main positive contactor 141, a precharge contactor 143, and a main negative contactor 145. The main positive contactor 141 may be connected to the positive electrical connector 121, and the main negative contactor 145 may be connected to the negative electrical connector 123. The main positive contactor 141 and the main negative contactor 145 may be configured to connect and/or disconnect the battery subpacks 110A-110D with and/or from an external device, for example, by closing/opening the main positive contactor 141 and the main negative contactor 145. Examples of the external device may include a battery charger (e.g., for charging the battery subpacks 110A-110D) and a battery backup system (e.g., for providing power from the battery subpacks 110A-110D to houses, offices, stores, restaurants, or any other suitable facilities, for example, during power outages). In some examples, the master microprocessor 131 may be configured to control (e.g., open/close, etc.) the main positive contactor 141, precharge contactor 143, and main negative contactor 145, and/or any other components of the system 100.

In some examples, the master microprocessor 131 may be configured to sort the plurality of battery subpacks 110A-110D according to the voltage value of the battery subpacks. As used herein, a voltage value of a battery subpack may refer to a voltage value of a battery module of the corresponding battery subpack. The master microprocessor 131 may also determine whether a difference between a voltage value of a first battery subpack (e.g., 110A) and a voltage value of a second battery subpack (e.g., 110B) is equal to or less than a first predetermined threshold value. Responsive to determining that the difference between the voltage value of the first battery subpack and the voltage value of the second battery subpack is equal to or less than the first predetermined threshold value, the master microprocessor 131 may connect the first battery subpack with the second battery subpack, for example, by closing contactors of the first and second battery subpacks.

In some examples, the connection of the first battery subpack with the second battery subpack may be implemented in the following order. In this example, it is assumed that the voltage value of the second battery subpack is greater than the voltage value of the first battery subpack. First, the master microprocessor 131 may close a negative contactor (e.g., 117A) of the first battery subpack (e.g., 110A) and a negative contactor (e.g., 117B) of the second battery subpack (e.g., 110B). Then, the master microprocessor 131 may close a positive contactor (e.g., 115A) of the first battery subpack (e.g., 110A), followed by closing an auxiliary positive contactor (e.g., 116B) of the second battery subpack (e.g., 110B). In other examples, the master microprocessor 131 may close the negative contactor (e.g., 117A) of the first battery subpack (e.g., 110A), and then close the positive contactor (e.g., 115A) of the first battery subpack (e.g., 110A). After the positive contactor (e.g., 115A) of the first battery subpack (e.g., 110A) is closed, the master microprocessor 131 may close the negative contactor (e.g., 117B) of the second battery subpack (e.g., 110B). Then, the master microprocessor 131 may close the auxiliary positive contactor (e.g., 116B) of the second battery subpack (e.g., 110B).

After the auxiliary positive contactor (e.g., 116B) of the second battery subpack (e.g., 110B) is closed, the master microprocessor 131 may close a positive contactor (e.g., 115B) of the second battery subpack (e.g., 110B). In some examples, after the auxiliary positive contactor (e.g., 116B) of the second battery subpack (e.g., 110B) is closed, the master microprocessor 131 may monitor the voltage/current value and/or the change to the voltage/current (e.g., inrush current), and wait for a predetermined amount of time before closing the positive contactor (e.g., 115B). In some examples, the predetermined amount of time may be in a range of 1 to 180 seconds. In other examples, the predetermined amount of time may be any suitable amount of time.

In some examples, after the auxiliary positive contactor (e.g., 116B) of the second battery subpack (e.g., 110B) is closed, the master microprocessor 131 may monitor the voltage/current value or change to the voltage/current value (e.g., inrush current) and wait until the current becomes equal to or less than a predetermined threshold current value I_{T} before closing the positive contactor (e.g., 115B). In some examples, the predetermined threshold current value I_{T} may be in a range of 30 A to 70 A, more preferably in a range of 40 A to 60 A, or 45 A to 55 A. For example, the predetermined threshold current value I_{T} may be 30 A, 35 A, 45 A, 50 A, 55 A, 60 A, 65 A, 70 A, or 75 A. In other examples, the predetermined threshold current value I_{T} may have any other suitable current value.

In some embodiments, subsequent to closing the positive contactor (e.g., 115B) of the second battery subpack (e.g., 110B), the master microprocessor 131 may open the auxiliary positive contactor (e.g., 116B) of the second battery subpack (e.g., 110B). When the voltage value of the first battery subpack is greater than the voltage value of the second battery subpack, the contactor closing/opening processes may be the opposite.

In some examples, the current of the battery modules 111A-111D/battery subpacks 110A-110D may be monitored by the subpack microprocessors 112A-112D through the cell monitoring circuit 113A-113D. In some examples, the subpack microprocessors 112A-112D/cell monitoring circuit 113A-113D may use the resistance of the auxiliary positive contactor 116A-116D / positive contactor 115A-115D for the calculation of the current. In this case, the battery subpacks 110A-110D may not have any resistors, other than the auxiliary positive contactor 116A-116D / positive contactor 115A-115D for the calculation of the current.

In some embodiments, the auxiliary positive contactor 116A-116D of each of the battery subpacks may be made with a material different from a material with which the positive contactor 115A-115D of each of the battery subpacks is made. The positive contactor 115A-115D of the battery subpacks may be made with at least one of copper, aluminum, nickel, gold, silver, tungsten, or any other suitable conductive material. The auxiliary positive contactor 116A-116D of the battery subpacks may be made with tungsten or any other suitable conductive material. In some examples, the resistance of the auxiliary positive contactor 116A-116D may be greater than the resistance of the positive contactor 115A-115D of the battery subpacks. In other examples, the positive contactor 115A-115D and auxiliary positive contactor 116A-116 may be made with the same materials and/or have the same resistance.

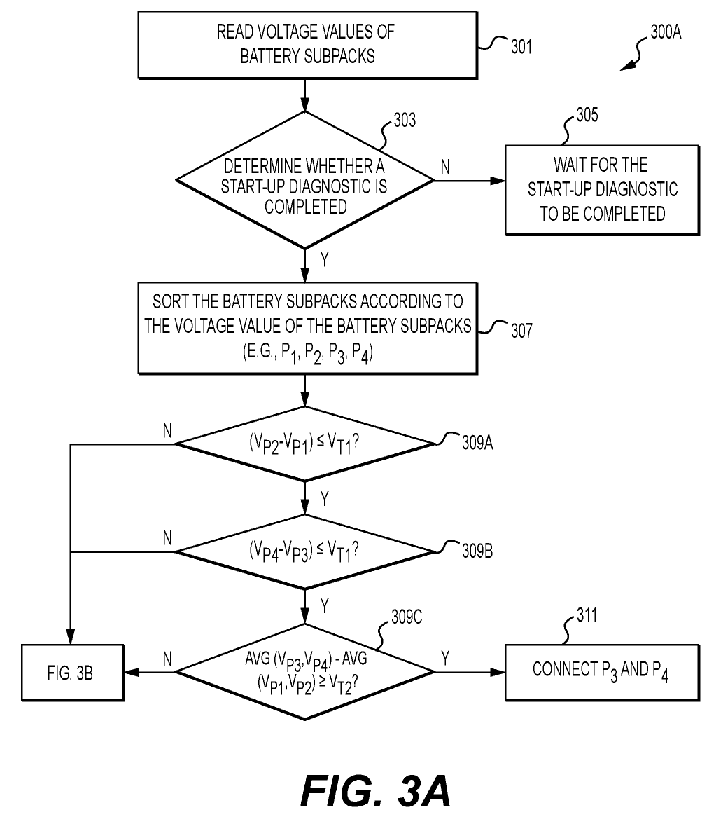

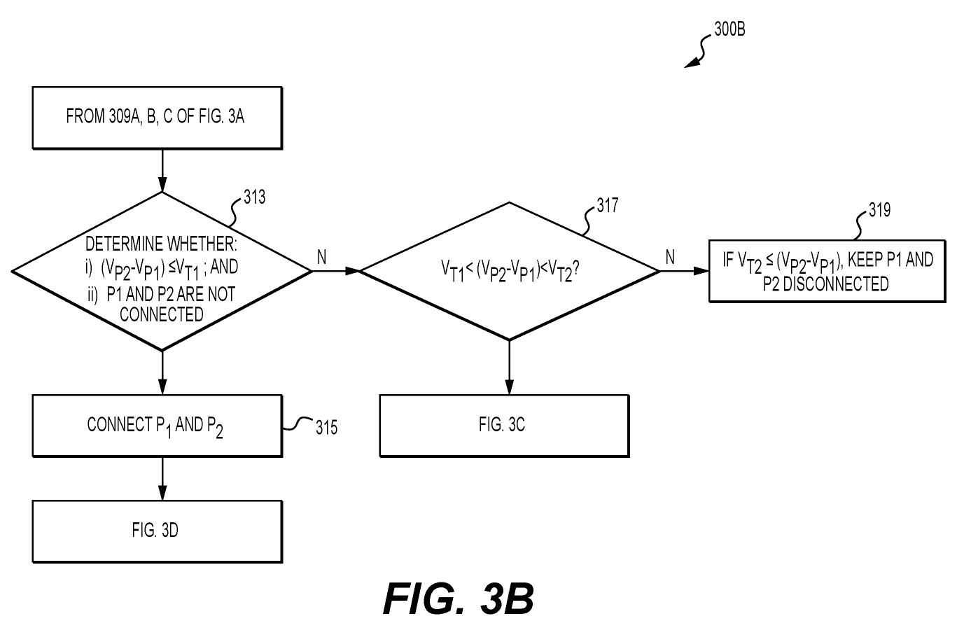

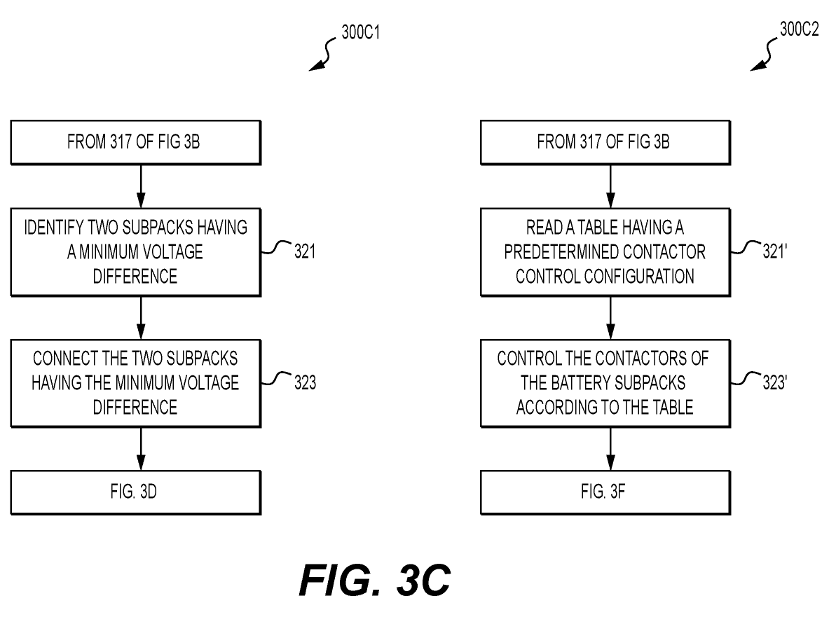

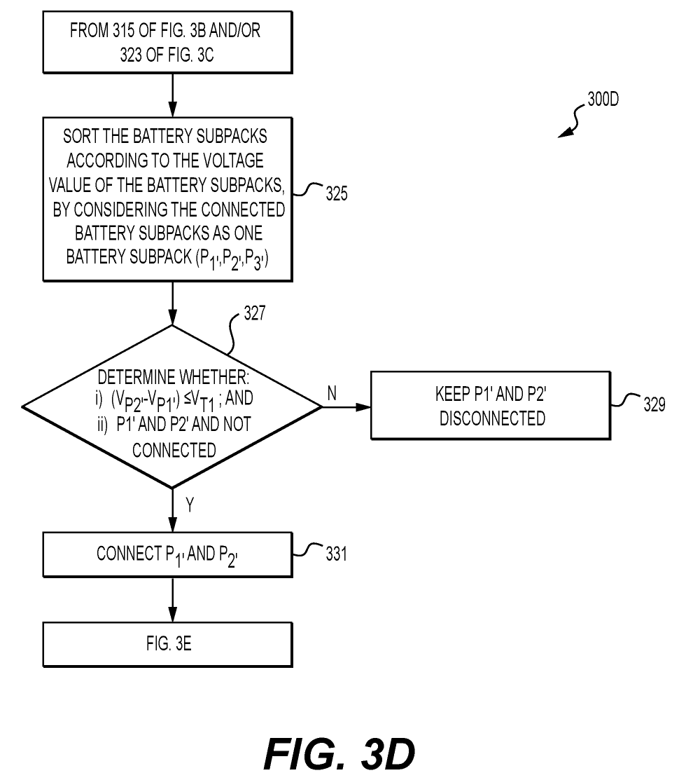

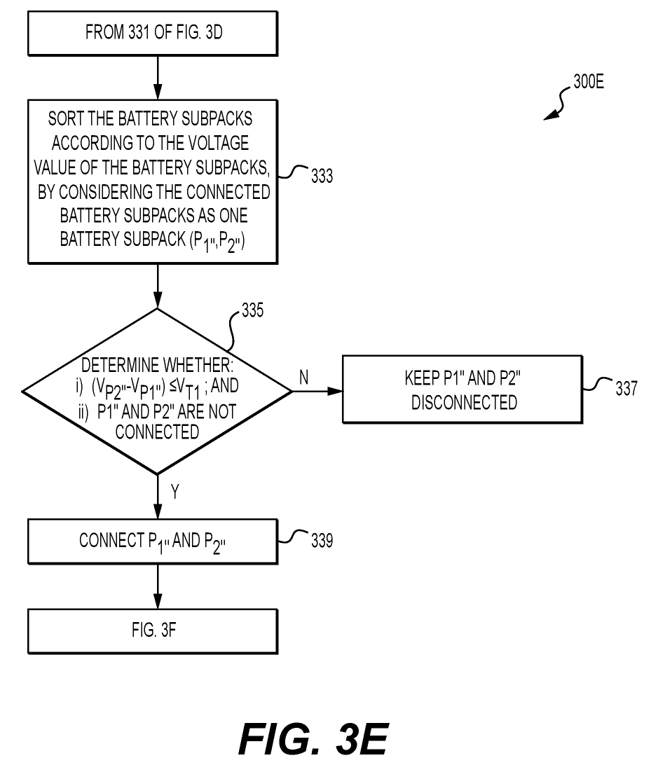

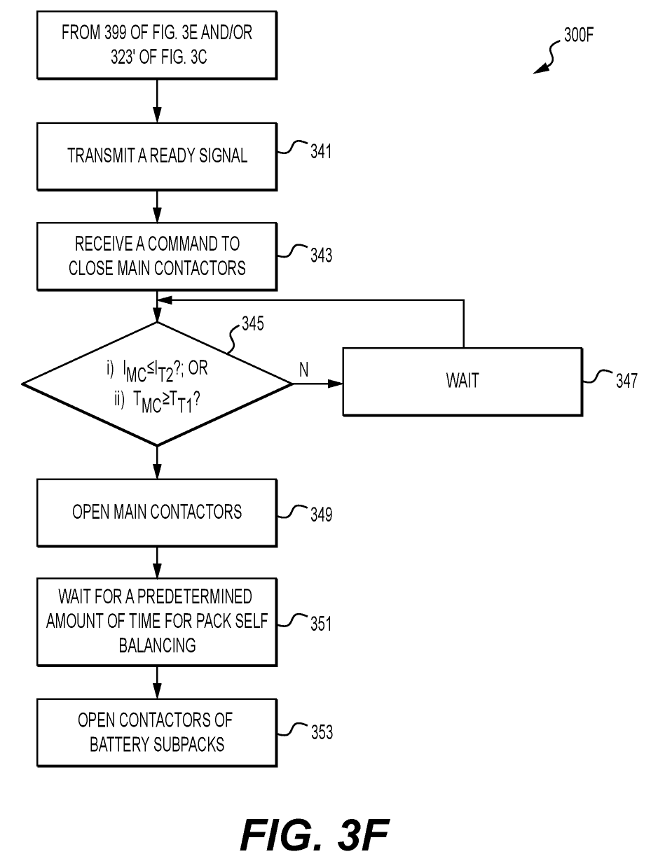

FIGS. 3A-3F illustrate a flow diagram of example methods 300A-300F for operating a plurality of battery subpacks according to an example embodiment of the present disclosure. Although the example methods 300A-300F are described with reference to the flow diagram illustrated in FIGS. 3A-3F, it will be appreciated that many other methods of performing the acts associated with the methods may be used. For example, the order of some of the blocks may be changed, certain blocks may be combined with other blocks, and some of the blocks described are optional.

In some examples, the master microprocessor 131 and/or the subpack microprocessor 112A-112D may perform one or more portions of the processes 300A-300F and may be implemented using, for instance, a chip set including a processor and a memory.

In the illustrated example, the master microprocessor 131 may read voltage values of battery subpacks (P_{A}, P_{B}, P_{C}, P_{D}) (block 301). For example, the master microprocessor 131 may receive information about voltage values of the battery subpacks 110A-110D in the system 100, for example, from respective subpack microprocessors 112A-112D.

Then, the master microprocessor 131 may determine whether a start-up diagnostic is completed (block 303). If the start-up diagnostic is not completed, the master microprocessor 131 may wait until the start-up diagnostic is completed (block 305).

If the start-up diagnostic is completed, the master microprocessor 131 may sort the battery subpacks according to the voltage value of the battery subpacks (block 307). For example, assuming that there are four battery subpacks, these four battery subpacks may be sorted in an ascending order from the lowest to the highest (P₁, P₂, P₃ P₄). In this case, the voltage value of P₄ may be equal to or greater than the voltage value of P_{3,} the voltage value of P₃ may be equal to or greater than the voltage value of P₂, and the voltage value of P₂ may be equal to or greater than the voltage value of P₁.

Then, the master microprocessor 131 may determine whether a difference between the voltage value V_{P1} of the first battery subpack P₁ and the voltage value V_{P2} of the second battery subpack P₂ is equal to or less than a first predetermined threshold value V_{T1} (block 309A). The master microprocessor 131 may also determine whether a difference between the voltage value V_{P3} of the third battery subpack P₃ and the voltage value V_{P4} of the fourth battery subpack P₄ is equal to or less than the first predetermined threshold value V_{T1} (block 309B). The master microprocessor 131 may further determine whether a difference between an average of the voltage values V_{P1},V_{P2} of the first and second battery subpacks P₁,P₂ and an average of the voltage values V_{P3},V_{P4} of the third and fourth battery subpacks P₃,P₄ is equal to or greater than a second predetermined threshold value V_{T2} (block 309C).

In some examples, the first predetermined threshold value V_{T1} may be in a range of 25 V to 75 V, more preferably in a range of 30 V to 70 V, 35 V to 65 V, 40 V to 60 V, or 45 V to 55 V. For example, the first predetermined threshold value V_{T1} may be 25V, 30 V, 35 V, 40 V, 45 V, 50 V, 55 V, 60 V, 65 V, 70V, or 75 V. In other examples, the first predetermined threshold value V_{T1} may have any other suitable voltage value.

In some examples, the first predetermined threshold value V_{T1} may be dependent on a threshold inrush current. For example, the first predetermined threshold value V_{T1} may be set to a voltage value where an inrush current that may be caused by a voltage difference in a given resistance (when two battery subpacks are connected) would become equal to or less than a predetermined threshold current value I_{T1}. For example, when the resistance of the contactors of the battery subpack(s) is 0.125 ohms and the predetermined threshold current value I_{T1} is 400 A, the first predetermined threshold value V_{T1} would become 50 V (i.e., V = I (400 A) * R (0.125 ohms)).

The predetermined threshold current value I_{T1} may be in a range of 300 A to 500 A, more preferably in a range of 350 A to 400 A, 350 A to 450 A, 375 A to 425 A, or 395 A to 405 A. For example, the predetermined threshold current value I_{T1} may be 300 A, 325 A, 350 A, 375 A, 400 A, 425 A, 450 A, 475 A, or 500 A. In other examples, the predetermined threshold current value I_{T1} may have any other suitable current value. In some examples, the predetermined threshold current value I_{T1} may be a maximum allowable inrush current or determined based on the maximum allowable inrush current (e.g., 70%, 80%, 90%, 95% of the maximum allowable inrush current).

In some examples, the first predetermined threshold value V_{T1} may change depending on the change in temperature. In some examples, the master microprocessor 131 may change the first predetermined threshold value V_{T1} according to the change to the temperature of the battery subpacks 110A-110D/battery modules 111A-111D.

In some examples, the second predetermined threshold value V_{T2} may be in a range of 75 V to 125 V, more preferably in a range of 80 V to 120 V, 85 V to 115 V, 90 V to 110 V, or 95 V to 105 V. For example, the second predetermined threshold value V_{T2} may be 75 V, 80 V, 85 V, 90 V, 95 V, 100 V, 105 V, 110 V, 115 V, 120 V, or 125 V. In other examples, the second predetermined threshold value V_{T2} may have any other suitable voltage value.

In some examples, the second predetermined threshold value V_{T2} may be greater than the first predetermined threshold value V_{T1}. In some examples, thesecond predetermined threshold value V_{T2} may be set as a voltage value that is 1.5 to 3 times of the first predetermined threshold value V_{T1}.

Although blocks 309A-309C are implemented in this order in FIG. 3A, the order of these blocks may be changed, and any of blocks 309A-309C can be implemented in any order: first, second, and third. In some examples, if any of the answers to blocks 309A-309C is no, the master microprocessor 131 may proceed to the next step (e.g., block 313) by skipping any remaining step among blocks 309A-309C.

If the answers to all of blocks 309A-309C are yes, the master microprocessor 131 may connect the third battery subpack P₃ with the fourth battery subpack P₄ (block 311). For example, the master microprocessor 131 may connect the third battery subpack P₃ with the fourth battery subpack P₄ by closing the contactors of the third and fourth battery subpacks. The connection of the third battery subpack P₃ with the fourth battery subpack P₄ may be implemented in the following order. First, the master microprocessor 131 may close a negative contactor of the third battery subpack P₃ and a negative contactor of the fourth battery subpack P₄. Then, the master microprocessor 131 may close a positive contactor of the third battery subpack P₃, followed by closing an auxiliary positive contactor of the fourth battery subpack P₄. In other examples, the master microprocessor 131 may close the negative contactor of the third battery subpack P₃, and then close the positive contactor of the third battery subpack P₃. After the positive contactor of the third battery subpack P₃ is closed, the master microprocessor 131 may close the negative contactor of the fourth battery subpack P₄. Then, the master microprocessor 131 may close the auxiliary positive contactor of the fourth battery subpack P₄.

After the auxiliary positive contactor of the fourth battery subpack P₄ is closed, the master microprocessor 131 may close a positive contactor of the fourth battery subpack P₄. In some embodiments, subsequent to closing the positive contactor of the fourth battery subpack P₄, the master microprocessor 131 may open the auxiliary positive contactor of the fourth battery subpack P₄.

In some examples, if any of the answers to blocks 309A-309C is no, the method may proceed with the steps illustrated in FIG. 3B. The master microprocessor 131 may determine whether the difference between the voltage value V_{P1} of the first battery subpack P₁ and the voltage value V_{P2} of the second battery subpack P₂ is equal to or less than the first predetermined threshold value V_{T1} and whether the first and second battery subpacks are not connected (block 313). In some examples, if the difference between the voltage value V_{P1} of the first battery subpack P₁ and the voltage value V_{P2} of the second battery subpack P₂ has been determined at block 309A, the master microprocessor 131 may not repeat the same inquiry and just check whether the first and second battery subpacks are not connected.

If it is determined that the difference between the voltage value V_{P1} of the first battery subpack P₁ and the voltage value V_{P2} of the second battery subpack P₂ is equal to or less than the first predetermined threshold value V_{T1} and the first and second battery subpacks are not connected, the master microprocessor 131 may connect the first battery subpack P₁ with the second battery subpack P₂ (block 315). The connection of the first battery subpack P₁ with the second battery subpack P₂ may be implemented in the same/similar order (e.g., the order of closing/opening the contactors) as discussed above with respect to the connection of the third battery subpack P₃ with the fourth battery subpack P₄ at block 311.

After the first battery subpack P₁ is connected with the second battery subpack P₂, the voltage value V_{P1} of the first battery subpack and the voltage value V_{P2} of the second battery subpack may become the same voltage value (e.g., average of V_{P1} and V_{P2} assuming that the capacity of the first and second battery subpacks is the same) For example, if the voltage value V_{P1} of the first battery subpack P₁ is 500 V and the voltage value V_{P2} of the second battery subpack P₂ is 550 V, the voltage value V_{P1-2} of the first and second battery subpacks P₁, P₂, after connection, may become 525 V.

Once the first battery subpack P₁ and the second battery subpack P₂ are connected to each other, the master microprocessor 131 may proceed to the method 300D illustrated in FIG. 3D. As illustrated in FIG. 3D, the master microprocessor 131 may sort the battery packs (P₁₋₂, P₃, P₄) according to the voltage value of the battery subpacks (block 325). In this case, the master microprocessor 131 may consider the first and second battery subpacks P₁₋₂, once connected, as one battery subpack (e.g., P_{1’}), for example, for purposes of battery pack balancing. In some examples, the battery subpacks (P₁₋₂, P₃, P₄) may be sorted in an ascending order from the lowest to the highest (P_{1’}, P_{2’}, P_{3’}).

Then, the master microprocessor 131 may determine whether the difference between the voltage value V_{P1’} of the first battery subpack P_{1’} (e.g., P₁₋₂) and the voltage value V_{P2’} of the second battery subpack P_{2’} (e.g., P₃) is equal to or less than the first predetermined threshold value V_{T1} and whether the first and second battery subpacks P_{1’}, P_{2’} are not connected (block 327). If it is determined that the difference between the voltage value V_{P1’} of the first battery subpack P_{1’} and the voltage value V_{P2’} of the second battery subpack P_{2’} is not equal to or less than the first predetermined threshold value V_{T1}, the master microprocessor 131 may keep the first battery subpack P_{1’} and the second battery subpack P_{2’} disconnected (block 329).

If it is determined that the difference between the voltage value V_{P1’} of the first battery subpack P_{1’} and the voltage value V_{P2’} of the second battery subpack P_{2’} is equal to or less than the first predetermined threshold value V_{T1} and the first and second battery subpacks P_{1’},P_{2’} are not connected, the master microprocessor 131 may connect the first battery subpack P_{1’} with the second battery subpack P_{2’} (block 331).

For example, the master microprocessor 131 may close the contactors of the second battery subpack P_{2’} in the following order. First, the master microprocessor 131 may close a negative contactor of the second battery subpack P_{2’}. Then, the master microprocessor 131 may close an auxiliary positive contactor of the second battery subpack P_{2’}. After the auxiliary positive contactor of the second battery subpack P_{2’} is closed, the master microprocessor 131 may close a positive contactor of the second battery subpack P_{2’}. In some embodiments, subsequent to closing the positive contactor of the second battery subpack P_{2’}, the master microprocessor 131 may open the auxiliary positive contactor of the second battery subpack P_{2’}.

After the first battery subpack P_{1’} is connected with the second battery subpack P_{2’}, the voltage value V_{P1’} of the first battery subpack P_{1’} and the voltage value V_{P2’} of the second battery subpack P_{2’} may become the same voltage value (e.g., average of V_{P1’} and V_{P2’} assuming that the capacity of the first and second battery subpacks is the same) For example, if the voltage value V_{P1’} of the first battery subpack P_{1’} is 525 V and the voltage value V_{P2’} of the second battery subpack P_{2'} is 575 V, the voltage value V_{P1-2’} of the first and second battery subpacks P_{1’}, P_{2’}, after connection, may become 550 V.

Once the first battery subpack P_{1’} (e.g., P₁₋₂) and the second battery subpack P_{2’} (e.g., P₃) are connected to each other, the master microprocessor 131 may proceed to the method 300E illustrated in FIG. 3E. As illustrated in FIG. 3E, the master microprocessor 131 may sort the battery packs (e.g., P₁₋₂₋₃, P₄) according to the voltage value of the battery subpacks (block 333). In this case, the master microprocessor 131 may consider the connected battery subpacks (e.g., P₁₋₂₋₃) as one battery subpack (e.g., P_{1’’}). In some examples, the battery subpacks (P₁₋₂₋₃, P₄) may be sorted in an ascending order from the lowest to the highest (P_{1’’}, P_{2’’}).

Then, the master microprocessor 131 may determine whether the difference between the voltage value V_{P1’’} of the first battery subpack P_{1’’} and the voltage value V_{P2’’} of the second battery subpack P_{2’’} is equal to or less than the first predetermined threshold value V_{T1} and whether the first and second battery subpacks P_{1’’}, P_{2’’} are not connected (block 335). If it is determined that the difference between the voltage value V_{P1’’} of the first battery subpack P_{1’’} and the voltage value V_{P2’’} of the second battery subpack P_{2’’} is not equal to or less than the first predetermined threshold value V_{T1}, the master microprocessor 131 may keep the first battery subpack P_{1’’} and the second battery subpack P_{2’’} disconnected (block 337).

If it is determined that the difference between the voltage value V_{P1’’} of the first battery subpack P_{1’’} and the voltage value V_{P2’’} of the second battery subpack P_{2’’} is equal to or less than the first predetermined threshold value V_{T1} and the first and second battery subpacks P_{1’’},P_{2’’} are not connected, the master microprocessor 131 may connect the first battery subpack P_{1’’} with the second battery subpack P_{2’’} (block 339). The connection of the first battery subpack P_{1’’} with the second battery subpack P_{2’’} may be implemented in the same/similar order (e.g., the order of closing/opening the contactors) as discussed above with respect to the connection of the first battery subpack P_{1’} with the second battery subpack P_{2’} at block 331.

Once the first battery subpack P_{1’’} (e.g., P₁₋₂₋₃) and the second battery subpack P_{2’} (e.g., P₄) are connected to each other, the master microprocessor 131 may proceed to the method 300F illustrated in FIG. 3F. For example, as illustrated in FIG. 3F, once all of the battery subpacks are connected to each other, the master microprocessor 131 may transmit a ready signal to an upper level controller (e.g., a controller of a mobile device) (block 341). The ready signal may indicate that the master microprocessor 131 is ready to close the main contactors (e.g., the main positive contactor 141 and the main negative contactor 145). Then, the master microprocessor 131 may receive, from the upper level controller, a command to close the main contactors (block 343).

After receiving the command to close the main contactors, the master microprocessor 131 may close the main positive contactor 141 and the main negative contactor 145, thereby connecting the battery subpacks 110A-110D with an external device. Then, the master microprocessor 131 may determine i) whether the current I_{MC} of the battery pack/main contact(s) is equal to or less than a predetermined threshold current value I_{T2}, or ii) whether the amount of time T_{MC} that has lapsed after closing the main contactors is equal to or greater than a predetermined threshold amount of time T_{T1} (block 345). In some examples, one or more current sensors may be disposed at or near the main negative contactor 145, and monitor the current I_{MC} of the battery pack/main contact(s). In some examples, the predetermined threshold amount of time T_{T1} may be in a range of 5 to 20 seconds. In other examples, the predetermined threshold amount of time T_{T1} may be any other suitable amount of time.

If the current I_{MC} of the battery pack/main contact(s) is not equal to or less than a predetermined threshold current value I_{T2}, or the amount of time T_{MC} that has lapsed after closing the main contactors is not equal to or greater than the predetermined threshold amount of time T_{T1}, the master microprocessor 131 may wait, for example, for a predetermined amount of time (e.g., 1-2 seconds) while keeping the main contactors closed (block 347). After the predetermined amount of time, the master microprocessor 131 may repeat block 345.

If the current I_{MC} of the battery pack/main contact(s) is equal to or less than a predetermined threshold current value I_{T2}, or the amount of time T_{MC} that has lapsed after closing the main contactors is equal to or greater than the predetermined threshold amount of time T_{T1}, the master microprocessor 131 may open the main contactors (block 349). Then, the master microprocessor 131 may wait for a predetermined amount of time (e.g., 200-300 seconds) for pack self-balancing (block 351). In some examples, the predetermined amount of time for pack self-balancing may change depending on the change in temperature. In some examples, the master microprocessor 131 may monitor the balancing current and wait until the balancing current becomes equal to or lower than a predetermined current value (e.g., 30 A - 40 A). Then, the master microprocessor 131 may open contactors of the battery subpacks (block 353).

Referring back to FIG. 3B, if the master microprocessor 131 determines that the difference between the voltage value V_{P1} of the first battery subpack P₁ and the voltage value V_{P2} of the second battery subpack P₂ is not equal to or less than the first predetermined threshold value V_{T1},the master microprocessor 131 may determine whether the difference between the voltage value V_{P1} of the first battery subpack P₁ and the voltage value V_{P2} of the second battery subpack P₂ is greater than the first predetermined threshold value V_{T1} and less than the second predetermined threshold value V_{T2} (block 317). If the master microprocessor 131 determines that the difference between the voltage value V_{P1} of the first battery subpack P₁ and the voltage value V_{P2} of the second battery subpack P₂ is equal to or greater than the second predetermined threshold value V_{T2}, the master microprocessor 131 may keep the first battery subpack P₁ and the second battery subpack P₂ disconnected (block 319). If the master microprocessor 131 determines that the difference between the voltage value V_{P1} of the first battery subpack P₁ and the voltage value V_{P2} of the second battery subpack P₂ is greater than the first predetermined threshold value V_{T1} and less than the second predetermined threshold value V_{T2}, the master microprocessor 131 may proceed to the method 300C1 or 300C2 illustrated in FIG. 3C.

In some examples, responsive to determining that the difference between the voltage value V_{P1} of the first battery subpack P₁ and the voltage value V_{P2} of the second battery subpack P₂ is greater than the first predetermined threshold value V_{T1} and less than the second predetermined threshold value V_{T2}, the master microprocessor 131 may identify two battery subpacks, among the battery subpacks (e.g., P₁, P₂, P₃ P₄), having a minimum voltage difference (block 321). Then, the master microprocessor 131 may connect the two battery subpacks having the minimum voltage difference (block 323). For example, the master microprocessor 131 may identify that the second battery subpack P₂ and the third battery subpack P₃ have the minimum voltage difference, and connect these two battery subpacks, for example, by closing the contactors of the these battery subpacks. The connection of the second battery subpack P₂ with the third battery subpack P₃ may be implemented in the same/similar order (e.g., the order of closing/opening the contactors) as discussed above with respect to the connection of the third battery subpack P₃ with the fourth battery subpack P₄ at block 311.

If there are more than one group of two battery subpacks having a minimum voltage difference, the master microprocessor 131 may connect the group of two battery subpacks having a higher capacity. For example, assuming that battery subpacks P₁, P₂, P₃ P₄ have a voltage value of 500 V, 575 V, 600 V, and 625 V, both of the group of P₂ and P₃ and the group of P₃ and P₄ have the same minimum voltage difference of 25 V. In this case, the master microprocessor 131 may connect P₃ with P₄ because the group of P₃ and P4 (e.g., 612.5 V on average) has a higher capacity than the group of P2 and P3 (e.g., 587.5 V on average).

In some examples, before connecting the two battery subpacks having the minimum voltage difference, the master microprocessor 131 may determine whether the difference of the voltage values of the two battery subpacks having the minimum voltage difference is equal to or less than the first predetermined threshold value V_{T1}. Responsive to determining that the difference of the voltage values of the these two battery subpacks is equal to or less than the first predetermined threshold value V_{T1}, the master microprocessor 131 may connect these two battery subpacks. If it is determined that the difference of the voltage values of the these two battery subpacks is not equal to or less than the first predetermined threshold value V_{T1}, the master microprocessor 131 may keep these two battery subpacks disconnected. Once the two battery subpacks having the minimum voltage difference are connected, the master microprocessor 131 may proceed to the steps illustrated in FIG. 3D.

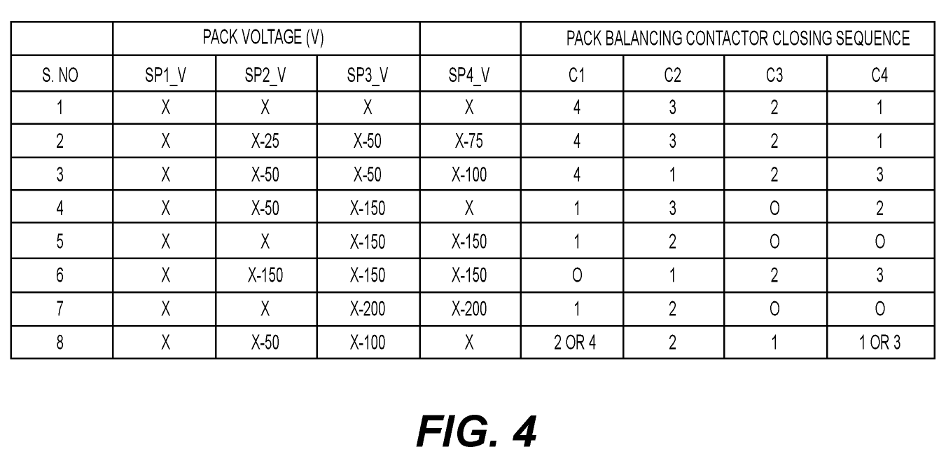

Referring to method 300C2, in some other examples, if the master microprocessor 131 determines that the difference between the voltage value V_{P1} of the first battery subpack P₁ and the voltage value V_{P2} of the second battery subpack P₂ is greater than the first predetermined threshold value V_{T1} and less than the second predetermined threshold value V_{T2} at block 317, the master microprocessor 131 may read a table having a predetermined contactor control configuration (block 321’). An example of the table is illustrated in FIG. 4. As shown in FIG. 4, the table may have the order of the battery subpacks that need to be closed in a given voltage/charge status of the battery subpacks.

For example, when the battery subpacks SP1, SP2, SP3, and SP4 have a voltage value of X, X-50, X-50, and X-100, respectively, the master microprocessor 131 may close SP2, SP3, SP4, and SP1 in this order according to the table (in view of Serial No. 3). When the battery subpacks SP1, SP2, SP3, and SP4 have a voltage value of X, X-50, X-150, and X, respectively, the master microprocessor 131 may close SP1, SP4, and SP2 in this order and keep the contactors of SP3 open according to the table (in view of Serial No. 4). In this table, “O” may refer to opening (e.g., keep opening) the contactors of the given battery subpack. When the battery subpacks SP1, SP2, SP3, and SP4 have a voltage value of X, X-50, X-100, and X, respectively, the master microprocessor 131 may close SP3, SP2, SP4, and SP1 in this order, or close SP4 and SP1 in this order (in view of Serial No. 8). In other examples, when the battery subpacks SP1, SP2, SP3, and SP4 have a voltage value of X, X-50, X-100, and X, respectively, the master microprocessor 131 may close SP4, SP1, SP2, and SP3 in this order, for example, in view of the table.

In some examples, the table may further include information about a predetermined amount of time that is needed between closing one battery subpack and closing the next battery subpack. In some examples, the predetermined amount of time may be in a range of 1 to 180 seconds. In some other examples, the predetermined amount of time may be any suitable amount of time. In some examples, the predetermined amount of time may be applied to all or portion of the serial numbers, and/or only between some battery subpacks in a given serial number.

After all the battery subpacks are connected to each other by controlling the contactors of the battery subpacks according to the table, the master microprocessor 131 may proceed to the method 300F illustrated in FIG. 3F. In some examples, the master microprocessor 131 may control the contactors of the battery subpacks according to the table, for example, from the beginning by overriding the steps described at blocks 307-339. For example, after the start-up diagnostic is completed at block 303, the master microprocessor 131 may read the table and control the contactors of the battery subpacks according to the table until it proceeds to the method 300F illustrated in FIG. 3F.

Although the methods illustrated in FIGS. 3A-3F are described mainly assuming that there are four battery subpacks, these methods can be applied/implemented when there are more or less than four battery subpacks.

For example, when there are less than four battery subpacks, the master microprocessor may proceed to block 325 (e.g., when there are three battery subpacks) or block 333 (e.g., when there are two battery subpacks), for example, after completing the start-up diagnostic at block 303.

In some examples, when there are more than four battery subpacks (e.g., P₁, P₂, … Pₙ₋₁, Pₙ), the master microprocessor 131 may use the lowest two battery subpacks P₁, P₂ for blocks 309A and 309C and the highest two battery subpacks Pₙ₋₁, Pₙ (instead of P₃, P₄) for blocks 309B, 309C, and 311. For example, in this case, block 309B would become “(V_{Pn-1}-V_{Pn}) ≤ V_{T1}?”, block 309C would become “Avg (V_{Pn-1}, V_{Pn}) - Avg (V_{P1}, V_{P2}) ≥ V_{T2}?”, and block 311 would become “connect Pn-1 and Pn.” Similar changes can be made to other blocks illustrated in FIGS. 3B-3F. In particular, the steps in FIGS. 3B-3E may be repeated until all battery subpacks in the system or all battery subpacks having a voltage difference less than the first predetermined threshold value V_{T1} are connected to each other (before proceeding to the method 300F).

In some other examples, when there are more than four battery subpacks (e.g., P₁, P₂, … Pₙ₋₁, Pₙ), the master microprocessor 131 may use the lowest two battery subpacks P₁, P₂ for blocks 309A and 309C and the next two lowest battery subpacks P₃, P₄ for blocks 309B, 309C, and 311. In this case, the steps in FIGS. 3B-3E may be repeated until all battery subpacks in the system or all battery subpacks having a voltage difference less than the first predetermined threshold value V_{T1} are connected to each other (before proceeding to the method 300F).

In some examples, when there are more than four battery subpacks (e.g., P₁, P₂, … Pₙ₋₁, Pₙ), the master microprocessor 131 may use the highest two battery subpacks Pₙ₋₁, Pₙ (instead of P₃, P₄) for blocks 309B, 309C, and 311, and the next two highest two battery subpacks Pₙ₋₃, Pₙ₋₂ (instead of P₁, P₂) for blocks 309A and 309C. Similar changes can be made to other blocks illustrated in FIGS. 3B-3F. In particular, the steps in FIGS. 3B-3E may be repeated until all battery subpacks in the system or all battery subpacks having a voltage difference less than the first predetermined threshold value V_{T1} are connected to each other (before proceeding to the method 300F).

In some examples, when there are more than four battery subpacks (e.g., P₁, P₂, … Pₙ₋₁, Pₙ), the master microprocessor 131 may use any four adjacent battery subpacks (in terms of the order as a result of the sorting at block 307). For example, P₇, P₈ (instead of P₃, P₄) may be used for blocks 309B, 309C, and 311, and P₅, P₆ (instead of P₁, P₂) may be used for blocks 309A and 309C. Similar changes can be made to other blocks illustrated in FIGS. 3B-3F. In particular, the steps in FIGS. 3B-3E may be repeated until all battery subpacks in the system or all battery subpacks having a voltage difference less than the first predetermined threshold value V_{T1} are connected to each other (before proceeding to the method 300F).

In some other examples, when there are more or less than four battery subpacks, the master microprocessor 131 may control the contactors of the battery subpacks according to a table having a predetermined contactor control configuration (a table similar to the one illustrated in FIG. 4). In some examples, there are multiple tables for different number of battery subpacks. In some examples, the master microprocessor 131 may control the contactors of the battery subpacks according to the table(s) after the start-up diagnostic is completed at block 303 until it proceeds to the method 300F illustrated in FIG. 3F.

In some examples, all or some of the functions performed by the master microprocessor 131 may be performed by one or more of the subpack microprocessors 110A-110D. In some examples, one of the subpack microprocessors 110A-110D may serve as a master microprocessor performing all or some of the functions performed by the master microprocessor 131. In this case, there may be no separate master controller 130/ master microprocessor 131. In some examples, all or some of the functions performed by one or more of the subpack microprocessors 110A-110D may be performed by the master microprocessor 131.

The general discussion of this disclosure provides a brief, general description of a suitable computing environment in which the present disclosure may be implemented. In some examples, any of the disclosed systems, methods, and/or graphical user interfaces may be executed by or implemented by a computing system consistent with or similar to that depicted and/or explained in this disclosure. Although not required, aspects of the present disclosure are described in the context of computer-executable instructions, such as routines executed by a data processing device, e.g., a server computer, wireless device, and/or personal computer. Those skilled in the relevant art will appreciate that aspects of the present disclosure can be practiced with other communications, data processing, or computer system configurations, including: Internet appliances, hand-held devices (including personal digital assistants (“PDAs”)), wearable computers, all manner of cellular or mobile phones (including Voice over IP (“VoIP”) phones), dumb terminals, media players, gaming devices, virtual reality devices, multi-processor systems, microprocessor-based or programmable consumer electronics, set-top boxes, network PCs, mini-computers, mainframe computers, and the like. Indeed, the terms “computer,” “server,” and the like, are generally used interchangeably herein, and refer to any of the above devices and systems, as well as any data processor.

Aspects of the present disclosure may be embodied in a special purpose computer and/or data processor that is specifically programmed, configured, and/or constructed to perform one or more of the computer-executable instructions explained in detail herein. While aspects of the present disclosure, such as certain functions, are described as being performed exclusively on a single device, the present disclosure may also be practiced in distributed environments where functions or modules are shared among disparate processing devices, which are linked through a communications network, such as a Local Area Network (“LAN”), Wide Area Network (“WAN”), and/or the Internet. Similarly, techniques presented herein as involving multiple devices may be implemented in a single device. In a distributed computing environment, program modules may be located in both local and/or remote memory storage devices.

Aspects of the present disclosure may be stored and/or distributed on non-transitory computer-readable media, including magnetically or optically readable computer discs, hard-wired or preprogrammed chips (e.g., EEPROM semiconductor chips), nanotechnology memory, biological memory, or other data storage media. Alternatively, computer implemented instructions, data structures, screen displays, and other data under aspects of the present disclosure may be distributed over the Internet and/or over other networks (including wireless networks), on a propagated signal on a propagation medium (e.g., an electromagnetic wave(s), a sound wave, etc.) over a period of time, and/or they may be provided on any analog or digital network (packet switched, circuit switched, or other scheme).

Program aspects of the technology may be thought of as “products” or “articles of manufacture” typically in the form of executable code and/or associated data that is carried on or embodied in a type of machine-readable medium. “Storage” type media include any or all of the tangible memory of the computers, processors or the like, or associated modules thereof, such as various semiconductor memories, tape drives, disk drives and the like, which may provide non-transitory storage at any time for the software programming. All or portions of the software may at times be communicated through the Internet or various other telecommunication networks. Such communications, for example, may enable loading of the software from one computer or processor into another, for example, from a management server or host computer of the mobile communication network into the computer platform of a server and/or from a server to the mobile device. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links, or the like, also may be considered as media bearing the software. As used herein, unless restricted to non-transitory, tangible “storage” media, terms such as computer or machine “readable medium” refer to any medium that participates in providing instructions to a processor for execution. In some examples, the master microprocessor 131 may be part of a computing system/special purpose computer described above (e.g., a processor).

The terminology used above may be interpreted in its broadest reasonable manner, even though it is being used in conjunction with a detailed description of certain specific examples of the present disclosure. Indeed, certain terms may even be emphasized above; however, any terminology intended to be interpreted in any restricted manner will be overtly and specifically defined as such in this Detailed Description section. Both the foregoing general description and the detailed description are exemplary and explanatory only and are not restrictive of the features, as claimed.

As used herein, the terms “comprises,” “comprising,” “having,” including,” or other variations thereof, are intended to cover a non-exclusive inclusion such that a process, method, article, or apparatus that comprises a list of elements does not include only those elements, but may include other elements not expressly listed or inherent to such a process, method, article, or apparatus.

As used herein, “about,” “approximately,” “generally,” and “substantially” are understood to refer to numbers in a range of numerals, for example the range of -10% to +10% of the referenced number, preferably -5% to +5% of the referenced number, more preferably -1% to +1% of the referenced number, most preferably -0.1% to +0.1% of the referenced number. Moreover, these numerical ranges should be construed as providing support for a claim directed to any number or subset of numbers in that range. For example, a disclosure of from 1 to 10 should be construed as supporting a range of from 1 to 5, from 3 to 6, from 1 to 9, from 2.5 to 4.7, from 2.2 to 9.9, and so forth.

As used herein, the term "electrically connected" may mean that the referenced elements are directly or indirectly connected in such a way as to allow electric current to flow between them.

It is noted that the hereinafter-used terms “attachable”, “attached”, “connectable”, and “connected” include, respectively, directly or indirectly attachable, directly or indirectly attached, directly or indirectly connectable, and directly or indirectly connected.

When the position relation between two parts is described using the terms such as “on,” “above,” “below,” “under,” and “next,” one or more parts may be positioned between the two parts unless the terms are used with the term “immediately” or “directly.” Similarly, as used herein, the terms “attachable”, “attached”, “connectable”, “connected” or any similar terms may include directly or indirectly attachable, directly or indirectly attached, directly or indirectly connectable, and directly or indirectly connected.

In those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that typically a disjunctive word and/or phrase presenting two or more alternative terms, whether in the description, claims, or drawings, should be understood to contemplate the possibilities of including one of the terms, either of the terms, or both terms unless context dictates otherwise. For example, the phrase “A or B” will be typically understood to include the possibilities of “A” or “B” or “A and B.”

Additionally, in describing the components of the present invention, there may be terms used like first, second, A, B, (a), and (b). These may be for the purpose of differentiating one component from the other but not to imply or suggest the substances, order, sequence, or number of the components unless the context dictates otherwise.

The term “exemplary” is used in the sense of “example” rather than “ideal.” As used herein, the singular forms “a,” “an,” and “the” include plural reference unless the context dictates otherwise.

Other embodiments of the disclosure will be apparent to those skilled in the art from consideration of the specification and practice of the invention disclosed herein. It is intended that the specification and examples be considered as exemplary only, with a true scope and spirit of the invention being indicated by the following claims.

Aspects of the present disclosure may offer a simple, cost-effective, and efficient solution to pack imbalance in parallel battery packs. By leveraging the inrush current rating of contactors, for example, by connecting battery subpacks (only) when they have a voltage difference equal to or less than a predetermined threshold value (which may be determined based on a predetermined threshold current value/maximum allowable inrush current), the system according to an example of the present disclosure can balance packs effectively, improving overall system performance and longevity.

### EXAMPLES

The present disclosure furthermore relates to the following aspects.

Example 1. A battery system comprising: a plurality of battery subpacks, each of the battery subpacks comprising: a battery module; a primary positive contactor; an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module; a negative contactor being electrically connected to the negative terminal of the battery module; and a subpack microprocessor configured to open and close the primary positive contactor, the auxiliary positive contactor, and the negative contactor; and a master microprocessor in electrical communication with the subpack microprocessor of each of the battery subpacks, wherein the master microprocessor is configured to receive information about a voltage value of the battery module of each of the battery subpacks, wherein the plurality of battery subpacks comprise a first battery subpack and a second battery subpack, wherein the master microprocessor is further configured to: sort the plurality of battery subpacks according to the voltage value of the battery subpacks; determine whether a difference between a voltage value of the first battery subpack and a voltage value of the second battery subpack is equal to or less than a first predetermined threshold value; and responsive to determining that the difference between the voltage value of the first battery subpack and the voltage value of the second battery subpack is equal to or less than the first predetermined threshold value, connect the first battery subpack with the second battery subpack by closing contactors of the first and second battery subpacks.

Example 2. The battery system of example 1, wherein connecting the first battery subpack with the second battery subpack comprises: closing a negative contactor of the first battery subpack and a negative contactor of the second battery subpack; closing a positive contactor of the first battery subpack; closing an auxiliary positive contactor of the second battery subpack; and closing a positive contactor of the second battery subpack.

Example 3. The battery system of example 2, wherein connecting the first battery subpack with the second battery subpack further comprises: subsequent to closing the positive contactor of the second battery subpack, opening the auxiliary positive contactor of the second battery subpack.

Example 4. The battery system of any one of examples 2-3, wherein the voltage value of the second battery subpack is greater than the voltage value of the first battery subpack.

Example 5. The battery system of any one of examples 1-4, wherein the auxiliary positive contactor of each of the battery subpacks is made with a material different from a material with which the positive contactor of each of the battery subpacks is made.

Example 6. The battery system of example 5, wherein the material of the auxiliary positive contactor comprises tungsten.

Example 7. A method of operating a battery system, wherein the battery system comprises: a plurality of battery subpacks, each of the battery subpacks comprising: a battery module; a primary positive contactor; an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module; a negative contactor being electrically connected to the negative terminal of the battery module; and a subpack microprocessor configured to open and close the primary positive contactor, the auxiliary positive contactor, and the negative contactor; and a master microprocessor in electrical communication with the subpack microprocessor of each of the battery subpacks, wherein the master microprocessor is configured to receive information about a voltage value of the battery module of each of the battery subpacks, wherein the plurality of battery subpacks comprise a first battery subpack and a second battery subpack, wherein the method comprises: sorting, by the master microprocessor, the plurality of battery subpacks according to the voltage value of the battery subpacks; determining, by the master microprocessor, whether a difference between a voltage value of the first battery subpack and a voltage value of the second battery subpack is equal to or less than a first predetermined threshold value; and responsive to determining that the difference between the voltage value of the first battery subpack and the voltage value of the second battery subpack is equal to or less than the first predetermined threshold value, connecting the first battery subpack with the second battery subpack by closing contactors of the first and second battery subpacks.

Example 8. The method of example 7, wherein connecting the first battery subpack with the second battery subpack comprises: closing a negative contactor of the first battery subpack and a negative contactor of the second battery subpack; closing a positive contactor of the first battery subpack; closing an auxiliary positive contactor of the second battery subpack; and closing a positive contactor of the second battery subpack.

Example 9. The method of example 8, wherein connecting the first battery subpack with the second battery subpack further comprises: subsequent to closing the positive contactor of the second battery subpack, opening the auxiliary positive contactor of the second battery subpack.

Example 10. The method of any one of examples 8-9, wherein the voltage value of the second battery subpack is greater than the voltage value of the first battery subpack.

Example 11. A battery system comprising: a plurality of battery subpacks, each of the battery subpacks comprising: a battery module; a primary positive contactor; an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module; a negative contactor being electrically connected to the negative terminal of the battery module; and a subpack microprocessor configured to open and close the primary positive contactor, the auxiliary positive contactor, and the negative contactor; and a master microprocessor in electrical communication with the subpack microprocessor of each of the battery subpacks, wherein the master microprocessor is configured to receive information about a voltage value of the battery module of each of the battery subpacks, wherein the plurality of battery subpacks comprise a first battery subpack, a second battery subpack, a third battery subpack, and a fourth battery subpack, wherein the master microprocessor is further configured to: sort the first, second, third, and fourth battery subpacks according to the voltage value of the first, second, third, and fourth battery subpacks, wherein a voltage value of the fourth battery subpack is equal to or greater than a voltage value of the third battery subpack, wherein a voltage value of the third battery subpack is equal to or greater than a voltage value of the second battery subpack, and wherein a voltage value of the second battery subpack is equal to or greater than a voltage value of the first battery subpack, determine whether a difference between the voltage value of the first battery subpack and the voltage value of the second battery subpack is equal to or less than a first predetermined threshold value; determine whether a difference between the voltage value of the third battery subpack and the voltage value of the fourth battery subpack is equal to or less than the first predetermined threshold value; and determine whether a difference between an average of the voltage values of the first and second battery subpacks and an average of the voltage values of the third and fourth battery subpacks is equal to or greater than a second predetermined threshold value.

Example 12. The battery system of example 11, wherein the master microprocessor is further configured to: responsive to determining that i) the difference between the voltage value of the first battery subpack and the voltage value of the second battery subpack is equal to or less than the first predetermined threshold value, ii) the difference between the voltage value of the third battery subpack and the voltage value of the fourth battery subpack is equal to or less than the first predetermined threshold value, and iii) the difference between the average of the voltage values of the first and second battery subpacks and the average of the voltage values of the third and fourth battery subpacks is equal to or greater than the second predetermined threshold value, connect the third battery subpack with the fourth battery subpack by closing contactors of the third and fourth battery subpacks.

Example 13. The battery system of any one of examples 11 and 12, wherein the master microprocessor is further configured to: responsive to determining that the difference between the voltage value of the first battery subpack and the voltage value of the second battery subpack is equal to or less than the first predetermined threshold value and i) the difference between the voltage value of the third battery subpack and the voltage value of the fourth battery subpack is not equal to or less than the first predetermined threshold value or ii) the difference between the average of the voltage values of the first and second battery subpacks and the average of the voltage values of the third and fourth battery subpacks is not equal to or greater than the second predetermined threshold value, connect the first battery subpack with the second battery subpack by closing contactors of the first and second battery subpacks, wherein, after the first battery subpack is connected with the second battery subpack, the voltage value of the first battery subpack and the voltage value of the second battery subpack become the same as a first-second battery subpack voltage value.

Example 14. The battery system of example 13, wherein the master microprocessor is further configured to, subsequent to connecting the first battery subpack with the second battery subpack: sort the first and second battery subpacks, the third battery subpack, and the fourth battery subpack, by considering the first and second battery subpacks as one battery subpack, according to the voltage value of the first and second battery subpacks, the third battery subpack, and the fourth battery subpack, determine whether a difference between the first-second battery subpack voltage value of the first and second battery subpacks and the voltage value of the third battery subpack is equal to or less than the first predetermined threshold value.

Example 15. The battery system of example 14, wherein the master microprocessor is further configured to, responsive to determining that the difference between the first-second battery subpack voltage value of the first and second battery subpacks and the voltage value of the third battery subpack is equal to or less than the first predetermined threshold value, connect the third battery subpack with the first and second battery subpacks by closing contactors of the third battery subpacks, wherein, after the third battery subpack is connected with the first and second battery subpacks, the voltage value of the third battery subpack and the first-second battery subpack voltage value of the first and second battery subpacks become the same as a first-second-third battery subpack voltage value.

Example 16. The battery system of example 15, wherein the master microprocessor is further configured to, subsequent to connecting the third battery subpack with the first and second battery subpacks: sort the first, second, and third battery subpacks and fourth battery subpack, by considering the first, second, and third battery subpacks as one battery subpack, according to the voltage value of the first, second, and third battery subpacks and the fourth battery subpack, determine whether a difference between the first-second-third battery subpack voltage value of the first, second, and third battery subpacks and the voltage value of the fourth battery subpack is equal to or less than the first predetermined threshold value.

Example 17. The battery system of example 16, wherein the master microprocessor is further configured to, responsive to determining that the difference between the first-second-third battery subpack voltage value of the first, second, and third battery subpacks and the voltage value of the fourth battery subpack is equal to or less than the first predetermined threshold value, connect the fourth battery subpack with the first, second, and third battery subpacks by closing contactors of the fourth battery subpacks.

Example 18. The battery system of any one of examples 11-17, wherein the master microprocessor is further configured to: responsive to determining that the difference between the voltage value of the first battery subpack and the voltage value of the second battery subpack is not equal to or less than the first predetermined threshold value and the difference between the average of the voltage values of the first and second battery subpacks and the average of the voltage values of the third and fourth battery subpacks is not equal to or greater than the second predetermined threshold value, determine whether the difference between the voltage value of the first battery subpack and the voltage value of the second battery subpack is greater than the first predetermined threshold value and less than the second predetermined threshold value.

Example 19. The battery system of example 18, wherein the master microprocessor is further configured to: responsive to determining that the difference between the voltage value of the first battery subpack and the voltage value of the second battery subpack is greater than the first predetermined threshold value and less than the second predetermined threshold value, identify two battery subpacks, among the first, second, third, and fourth battery subpacks, having a minimum voltage difference; and connect the two battery subpacks by closing contactors of the two battery subpacks.

Example 20. The battery system of any one of examples 18 and 19, wherein the master microprocessor is further configured to: responsive to determining that the difference between the voltage value of the first battery subpack and the voltage value of the second battery subpack is greater than the first predetermined threshold value and less than the second predetermined threshold value, control the contactors of the first, second, third, and fourth battery subpacks according to a table having a predetermined contactor control configuration.

What is claimed is:

1. A battery system comprising:
a plurality of battery subpacks, each of the battery subpacks comprising:
a battery module;
a primary positive contactor;
an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module;
a negative contactor being electrically connected to the negative terminal of the battery module; and
a subpack microprocessor configured to open and close the primary positive contactor, the auxiliary positive contactor, and the negative contactor; and
a master microprocessor in electrical communication with the subpack microprocessor of each of the battery subpacks, wherein the master microprocessor is configured to receive information about a voltage value of the battery module of each of the battery subpacks,
wherein the plurality of battery subpacks comprise a first battery subpack and a second battery subpack,
wherein the master microprocessor is further configured to:
sort the plurality of battery subpacks according to the voltage value of the battery subpacks;
determine whether a difference between a voltage value of the first battery subpack and a voltage value of the second battery subpack is equal to or less than a first predetermined threshold value; and
responsive to determining that the difference between the voltage value of the first battery subpack and the voltage value of the second battery subpack is equal to or less than the first predetermined threshold value, connect the first battery subpack with the second battery subpack by closing contactors of the first and second battery subpacks.

2. The battery system of claim 1, wherein connecting the first battery subpack with the second battery subpack comprises:
closing a negative contactor of the first battery subpack and a negative contactor of the second battery subpack;
closing a positive contactor of the first battery subpack;
closing an auxiliary positive contactor of the second battery subpack; and
closing a positive contactor of the second battery subpack.

3. The battery system of claim 2, wherein connecting the first battery subpack with the second battery subpack further comprises:
subsequent to closing the positive contactor of the second battery subpack, opening the auxiliary positive contactor of the second battery subpack.

4. The battery system of claim 2, wherein the voltage value of the second battery subpack is greater than the voltage value of the first battery subpack.

5. The battery system of claim 1, wherein the auxiliary positive contactor of each of the battery subpacks is made with a material different from a material with which the positive contactor of each of the battery subpacks is made.

6. The battery system of claim 5, wherein the material of the auxiliary positive contactor comprises tungsten.

7. A method of operating a battery system, wherein the battery system comprises:
a plurality of battery subpacks, each of the battery subpacks comprising:
a battery module;
a primary positive contactor;
an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module;
a negative contactor being electrically connected to the negative terminal of the battery module; and
a subpack microprocessor configured to open and close the primary positive contactor, the auxiliary positive contactor, and the negative contactor; and
a master microprocessor in electrical communication with the subpack microprocessor of each of the battery subpacks, wherein the master microprocessor is configured to receive information about a voltage value of the battery module of each of the battery subpacks,
wherein the plurality of battery subpacks comprise a first battery subpack and a second battery subpack,
wherein the method comprises:
sorting, by the master microprocessor, the plurality of battery subpacks according to the voltage value of the battery subpacks;
determining, by the master microprocessor, whether a difference between a voltage value of the first battery subpack and a voltage value of the second battery subpack is equal to or less than a first predetermined threshold value; and
responsive to determining that the difference between the voltage value of the first battery subpack and the voltage value of the second battery subpack is equal to or less than the first predetermined threshold value, connecting the first battery subpack with the second battery subpack by closing contactors of the first and second battery subpacks.

8. The method of claim 7, wherein connecting the first battery subpack with the second battery subpack comprises:
closing a negative contactor of the first battery subpack and a negative contactor of the second battery subpack;
closing a positive contactor of the first battery subpack;
closing an auxiliary positive contactor of the second battery subpack; and
closing a positive contactor of the second battery subpack.

9. The method of claim 8, wherein connecting the first battery subpack with the second battery subpack further comprises:
subsequent to closing the positive contactor of the second battery subpack, opening the auxiliary positive contactor of the second battery subpack.

10. The method of claim 8, wherein the voltage value of the second battery subpack is greater than the voltage value of the first battery subpack.

11. A battery system comprising:
a plurality of battery subpacks, each of the battery subpacks comprising:
a battery module;
a primary positive contactor;
an auxiliary positive contactor, wherein the primary positive contactor and the auxiliary positive contactor are electrically connected in parallel to one another, wherein the primary positive contactor and the auxiliary positive contactor are electrically connected to a positive terminal of the battery module;
a negative contactor being electrically connected to the negative terminal of the battery module; and
a subpack microprocessor configured to open and close the primary positive contactor, the auxiliary positive contactor, and the negative contactor; and
a master microprocessor in electrical communication with the subpack microprocessor of each of the battery subpacks, wherein the master microprocessor is configured to receive information about a voltage value of the battery module of each of the battery subpacks,
wherein the plurality of battery subpacks comprise a first battery subpack, a second battery subpack, a third battery subpack, and a fourth battery subpack,
wherein the master microprocessor is further configured to:
sort the first, second, third, and fourth battery subpacks according to the voltage value of the first, second, third, and fourth battery subpacks, wherein a voltage value of the fourth battery subpack is equal to or greater than a voltage value of the third battery subpack, wherein a voltage value of the third battery subpack is equal to or greater than a voltage value of the second battery subpack, and wherein a voltage value of the second battery subpack is equal to or greater than a voltage value of the first battery subpack,
determine whether a difference between the voltage value of the first battery subpack and the voltage value of the second battery subpack is equal to or less than a first predetermined threshold value;
determine whether a difference between the voltage value of the third battery subpack and the voltage value of the fourth battery subpack is equal to or less than the first predetermined threshold value; and
determine whether a difference between an average of the voltage values of the first and second battery subpacks and an average of the voltage values of the third and fourth battery subpacks is equal to or greater than a second predetermined threshold value.

12. The battery system of claim 11, wherein the master microprocessor is further configured to: responsive to determining that i) the difference between the voltage value of the first battery subpack and the voltage value of the second battery subpack is equal to or less than the first predetermined threshold value, ii) the difference between the voltage value of the third battery subpack and the voltage value of the fourth battery subpack is equal to or less than the first predetermined threshold value, and iii) the difference between the average of the voltage values of the first and second battery subpacks and the average of the voltage values of the third and fourth battery subpacks is equal to or greater than the second predetermined threshold value, connect the third battery subpack with the fourth battery subpack by closing contactors of the third and fourth battery subpacks.

13. The battery system of claim 11, wherein the master microprocessor is further configured to: responsive to determining that the difference between the voltage value of the first battery subpack and the voltage value of the second battery subpack is equal to or less than the first predetermined threshold value and i) the difference between the voltage value of the third battery subpack and the voltage value of the fourth battery subpack is not equal to or less than the first predetermined threshold value or ii) the difference between the average of the voltage values of the first and second battery subpacks and the average of the voltage values of the third and fourth battery subpacks is not equal to or greater than the second predetermined threshold value, connect the first battery subpack with the second battery subpack by closing contactors of the first and second battery subpacks, wherein, after the first battery subpack is connected with the second battery subpack, the voltage value of the first battery subpack and the voltage value of the second battery subpack become the same as a first-second battery subpack voltage value.

14. The battery system of claim 13, wherein the master microprocessor is further configured to, subsequent to connecting the first battery subpack with the second battery subpack:
sort the first and second battery subpacks, the third battery subpack, and the fourth battery subpack, by considering the first and second battery subpacks as one battery subpack, according to the voltage value of the first and second battery subpacks, the third battery subpack, and the fourth battery subpack,
determine whether a difference between the first-second battery subpack voltage value of the first and second battery subpacks and the voltage value of the third battery subpack is equal to or less than the first predetermined threshold value.

15. The battery system of claim 14, wherein the master microprocessor is further configured to, responsive to determining that the difference between the first-second battery subpack voltage value of the first and second battery subpacks and the voltage value of the third battery subpack is equal to or less than the first predetermined threshold value, connect the third battery subpack with the first and second battery subpacks by closing contactors of the third battery subpacks, wherein, after the third battery subpack is connected with the first and second battery subpacks, the voltage value of the third battery subpack and the first-second battery subpack voltage value of the first and second battery subpacks become the same as a first-second-third battery subpack voltage value.

16. The battery system of claim 15, wherein the master microprocessor is further configured to, subsequent to connecting the third battery subpack with the first and second battery subpacks:
sort the first, second, and third battery subpacks and fourth battery subpack, by considering the first, second, and third battery subpacks as one battery subpack, according to the voltage value of the first, second, and third battery subpacks and the fourth battery subpack,
determine whether a difference between the first-second-third battery subpack voltage value of the first, second, and third battery subpacks and the voltage value of the fourth battery subpack is equal to or less than the first predetermined threshold value.

17. The battery system of claim 16, wherein the master microprocessor is further configured to, responsive to determining that the difference between the first-second-third battery subpack voltage value of the first, second, and third battery subpacks and the voltage value of the fourth battery subpack is equal to or less than the first predetermined threshold value, connect the fourth battery subpack with the first, second, and third battery subpacks by closing contactors of the fourth battery subpacks.

18. The battery system of claim 11, wherein the master microprocessor is further configured to: responsive to determining that the difference between the voltage value of the first battery subpack and the voltage value of the second battery subpack is not equal to or less than the first predetermined threshold value and the difference between the average of the voltage values of the first and second battery subpacks and the average of the voltage values of the third and fourth battery subpacks is not equal to or greater than the second predetermined threshold value, determine whether the difference between the voltage value of the first battery subpack and the voltage value of the second battery subpack is greater than the first predetermined threshold value and less than the second predetermined threshold value.

19. The battery system of claim 18, wherein the master microprocessor is further configured to:
responsive to determining that the difference between the voltage value of the first battery subpack and the voltage value of the second battery subpack is greater than the first predetermined threshold value and less than the second predetermined threshold value, identify two battery subpacks, among the first, second, third, and fourth battery subpacks, having a minimum voltage difference; and
connect the two battery subpacks by closing contactors of the two battery subpacks.

20. The battery system of claim 18, wherein the master microprocessor is further configured to:
responsive to determining that the difference between the voltage value of the first battery subpack and the voltage value of the second battery subpack is greater than the first predetermined threshold value and less than the second predetermined threshold value, control the contactors of the first, second, third, and fourth battery subpacks according to a table having a predetermined contactor control configuration.
